(19) United States
(12) Patent Application Publication
(10) Pub. No.: US 2026/0068648 A1
(43) Pub. Date: Mar. 5, 2026

(54) SEMICONDUCTOR STRUCTURE HAVING METAL-ORGANIC FRAMEWORK MATERIAL AND METHOD OF MANUFACTURING THE SAME

(71) Applicant: TAIWAN SEMICONDUCTOR MANUFACTURING COMPANY LTD., HSINCHU (TW)

(72) Inventors: KUANG-WEI YANG, HSINCHU CITY (TW); SHAO-KUAN LEE, KAOHSIUNG CITY (TW); TING-YA LO, HSINCHU (TW); HSIN-YEN HUANG, NEW TAIPEI CITY (TW); HSIAO-KANG CHANG, HSINCHU CITY (TW)

(21) Appl. No.: 18/822,323

(22) Filed: Sep. 2, 2024

(51) Int. Cl. H01L 23/532; H01L 21/3105; H01L 21/768; H01L 23/522; H01L 23/528

(52) U.S. Cl. CPC H01L 23/53295

(57) ABSTRACT

A semiconductor structure is provided. The semiconductor structure includes a substrate and a metallization structure over the substrate. The metallization structure includes a plurality of metal layers, a metal-ion-containing dielectric layer over at least one of the metal layers, and a conductive via laterally surrounded by the metal-ion-containing dielectric layer. A method of manufacturing a semiconductor structure is also provided.

### BACKGROUND

Moore's law has been the most powerful driver for the development of the microelectronic industry, it posits that the number of transistors on a microchip doubles approximately every two years, correlating with an exponential increase in computing power. Moore's law has been pivotal in driving advancements in semiconductor manufacturing, motivating continuous innovation to shrink transistor sizes and enhance performance. Alongside these efforts, the dielectric constant of insulating materials used in semiconductor processes has been widely concerned. Early semiconductor technologies primarily utilized silicon dioxide (SiO₂) as the main insulator due to its relatively high dielectric constant, which limits transistor packing density.

As transistor dimensions approached atomic scales, the limitations of traditional SiO₂ became apparent, prompting the development of low-k dielectric materials. These materials, characterized by lower dielectric constants than SiO₂, reduce capacitance between interconnects, thereby improving signal speed and reducing power consumption.

### BRIEF DESCRIPTION OF THE DRAWINGS

Aspects of the present disclosure are best understood from the following detailed description when read with the accompanying figures. It is noted that, in accordance with the standard practice in the industry, various structures are not drawn to scale. In fact, the dimensions of the various structures may be arbitrarily increased or reduced for clarity of discussion.

FIG. 1 illustrates a cross-sectional view of a semiconductor structure according to some embodiments of the present disclosure.

FIG. 2 illustrates a cross-sectional view of a semiconductor structure according to some embodiments of the present disclosure.

FIG. 3 illustrates a cross-sectional view of a semiconductor structure according to some embodiments of the present disclosure.

FIGS. 4A to 4H illustrate cross-sectional views of a method of manufacturing a semiconductor structure according to some embodiments of the present disclosure.

FIG. 5 illustrates a flow chat of a method for manufacturing a semiconductor structure according to some embodiments of the present disclosure.

FIGS. 6A to 6G illustrate cross-sectional views of a method of manufacturing a semiconductor structure according to some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first”, “second” and “third” describe various elements, components, regions, layers and/or sections, these elements, components, regions, layers and/or sections should not be limited by these terms. These terms may be only used to distinguish one element, component, region, layer, or section from another. The terms such as “first”, “second”, and “third” when used herein do not imply a sequence or order unless clearly indicated by the context.

The back-end-of-line (BEOL) structure in a semiconductor structure refers to the interconnect layers that are built over the transistors and/or some active devices on a substrate. Typically, these interconnect layers including a plurality of metal lines, a plurality of conductive vias electrically connected to the metal lines, and insulating materials surrounding the metal lines and conductive vias.

One of the aspects should be considered in forming the BEOL structure is the presence of RC delay, which refers to the resistance (R) and capacitance (C) that can slow down the signal propagation through the metal lines and the conductive vias (i.e., the interconnect path). Generally, the resistance comes from the metal lines and conductive vias, while the capacitance comes from the insulating materials between the metal lines, since the insulating material sandwiched by two adjacent metal lines could preformed a structure like to a metal-insulator-metal (MIM) capacitor, based on the fact that basically all capacitors store energy via electrical conductors (plates) separated by a dielectric (insulating) material. These factors (i.e., the resistance and capacitance) can lead to a delay in the transmission of signals, which can impact the overall performance of the integrated circuit.

In addition, the design of the layout of the interconnect layers can also have an impact on the RC delay. By optimizing the routing of the interconnect layers and minimizing the length of the signal paths, it is possible to reduce the overall resistance and capacitance, thereby improving the signal transmission speed.

There are several methods that can be used to reduce the RC delay in the BEOL structure under an aspect of material. In some comparative embodiments, it is possible to use low-resistance materials for the metal lines and conductive vias, such as copper (Cu) instead of aluminum (Al). This may help to reduce the resistance and improve the signal transmission speed. In other comparative embodiments, it is possible to use low-k dielectric materials for the insulating materials between the metal lines, which can reduce the capacitance and minimize the delay.

Furthermore, in some comparative embodiments, some other structures in the BEOL structure may cause RC delay, so there is room for improvement. For instance, in order to form the metal lines and conductive vias in the BEOL structure, a plurality of etch stop layer can be formed in each interconnect layers in the BEOL structure, while the etch stop layer itself has a less than ideal dielectric constant, so its presence conflicts with the goal of using low-k dielectric materials for the insulating layers as much as possible. In some comparative embodiments, the material of commonly used etch stop layer, which is usually silicon-based, may include silicon nitride (SiN), silicon carbide (SiC), silicon carbonitride (SiCN), or the like. The dielectric constant of silicon nitride (SiN) can be in a range from about 6.0 to about 7.5. The dielectric constant of silicon carbide (SiC) can be in a range from about 6.5 to about 10.0. The dielectric constant of silicon carbonitride (SiCN) can be in a range from about 3.0 to about 7.0. Comparing to the common material of insulating materials in the BEOL structure, such as silicon dioxide (SiO₂), fluorosilicate glass (FSG), or undoped silicate glass (USG), the dielectric constant of the material of some commonly used etch stop layer are relatively high.

Since the presence of the etch stop layer is not only related to the manufacturing process of metal lines and conductive vias, but also to the stability of the overall BEOL structure. Therefore, if the approach to improving the BEOL structure includes changing or modifying the etch stop layer, in addition to the needs of the process and the improvements in the value of dielectric constant, factors related to mechanical strength also need to be taken into account.

Accordingly, in some embodiments of the present disclosure, a layer with an ultra-low dielectric constant (i.e., ultra-low-k) is integrated into the BEOL structure of the semiconductor structure, where the ultra-low-k layer can include a metal-organic framework (MOF) material. On the other hand, in some embodiments of the present disclosure, the insulating material used in the BEOL structure can include a metal-containing material with an ultra-low dielectric constant. This differs from the scenario where non-metallic materials, such as silicon-based etch stop layers or silicon-based interlayer dielectric (ILD), occupy the spaces between the metal lines and conductive vias in the BEOL structure.

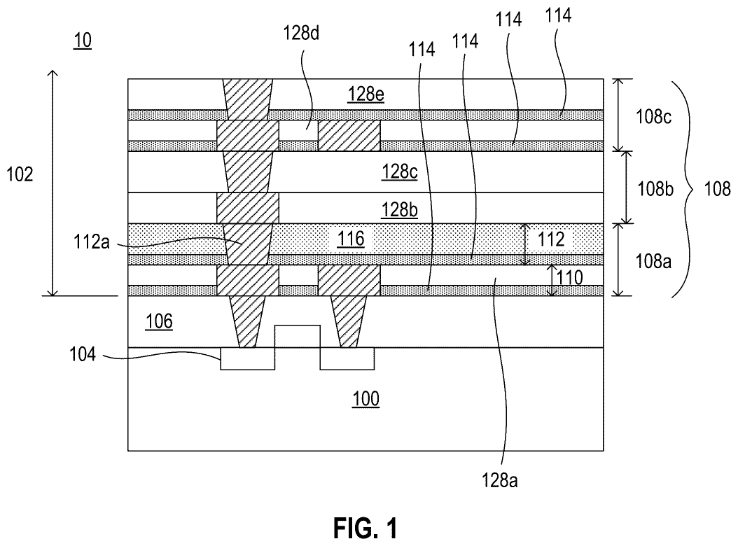

Referring to FIG. 1, in some embodiments, a semiconductor structure 10 includes a substrate 100 and a metallization structure 102 over the substrate 100. In some embodiments, a front-end-of-line (FEOL) structure 104 and/or a middle-end-of-line (MEOL) structure 106 can be formed over the substrate 100 subsequently prior to the forming of the metallization structure 102.

In some embodiments, the substrate 100 is a silicon substrate. In some embodiments, the substrate 100 may be made by some other semiconductor material such as germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations thereof, and the like, may also be used. Additionally, the substrate 100 may include a silicon-on-insulator (SOI) substrate. Generally, an SOI substrate includes a layer of semiconductor material such as epitaxial silicon, germanium, silicon germanium, SOI, silicon germanium on insulator (SGOI), or combinations thereof. The substrate 100 may be doped with a p-type dopant such as boron, boron fluorine, aluminum, gallium, or the like. The substrate may alternatively be doped with an n-type dopant such as phosphorus, arsenic, antimony, or the like.

The FEOL structure 104 is the one of the portions of IC fabrication where the components such as transistors are formed in the substrate 100. The FEOL structure 104 may include various kinds of individual devices. In some embodiments, the individual devices may include various microelectronic devices, for example, an image sensor such as metal-oxide-semiconductor field effect transistor (MOSFET), large scale integration (LSI) system, complementary metal-oxide-semiconductor (CMOS) imaging sensor (CIS), micro-electro-mechanical system (MEMS), active device, passive device, and the like. The individual devices may be electrically connected to a conductive region of the substrate 100.

The definitions of what is properly considered the MEOL structure 106 may vary, whereas in some embodiments of the present disclosure, the MEOL structure is referred to the region that formed over a surface of the substrate 100 and below a first metal layer (M1) of the metallization structure 102. In some embodiments, the material of the MEOL structure 106 includes dielectric material, which may be referred to as a pre-metal dielectric (PMD). In other words, the MEOL structure 106 can be distinguished from the substrate 100 there below and the metallization structure 102 thereon by a number of process parameters, such as the choice of the fundamental material, or the choice of the metal used. For instance, the material of the MEOL structure 106 can include low-k dielectric material with a small dielectric constant relative to silicon dioxide, and thus can be distinguished from the material of the substrate 100; likewise, the metal usually used in the MEOL structure 106 for electrical connect is tungsten (W), while the metals usually used in the metallization structure 102 is copper (Cu). These are several exemplary approaches to distinguish the stacked structures over the substrate 100.

The metallization structure 102 in the semiconductor structure 10 may refer to a BEOL structure under an aspect that interconnect layers formed after the individual devices have been fabricated. In some embodiments, metallization structure 102 includes a plurality of metal layers 108 (e.g., the metal layers 108a, 108b, 108c . . . 108x). Each of the metal layer 108 may have a metal line portion 110 and a conductive via portion 112 in contact with the metal line portion. In some embodiments, the metal layer 108 that is closest to the MEOL structure 106 may be referred to as the first metal layer, while the metal line portion 110 and the conductive via portion 112 (or the conductive structure within these portions) can be briefly called M1 and V1, respectively. Likewise, within the metal layers further stacked over the first metal layer, the metal line portions and the conductive via portions thereof can be briefly called M2, M3, M4, . . . Mx and V2, V3, V4, . . . Vx, respectively.

In some embodiments, the metallic material in the metal line portion 110 and the conductive via portion 112 (e.g., M1, V1, M2, V2, etc.) can be low resistance metals or binary metals such as copper (Cu), cobalt (Co), nickel (Ni), ruthenium (Ru), iridium (Ir), platinum (Pt), rhodium (Rh), iron cobalt (FeCo), iron aluminum (FeAl), or the like. In some embodiments, these low resistance metals or binary metals can be formed deposited by the manner of electrochemical plating (ECP), electroless deposition (ELD), or physical vapor deposition (PVD).

In some embodiments, the metallization structure 102 includes one or more etch stop layers 114. For instance, the etch stop layers 114 may be located in proximity to a bottom of each of the metal line portion 110 and the conductive via portion 112 of the metal layers 108. In some embodiments, the material of the etch stop layer 114 includes silicon nitride (SiN), silicon carbide (SiC), silicon carbonitride (SiCN), or the like. In some embodiments, the conductive structure within each of the metal line portion 110 and the conductive via portion 112 of the metal layers 108 are laterally surrounded by the etch stop layer 114. In some embodiments, the thickness of the etch stop layer 114 is less than the height of the conductive via portion 112.

In some embodiments, a metal-ion-containing dielectric layer 116 can be formed on one of the etch stop layer 114. In some embodiments, the metal-ion-containing dielectric layer 116 laterally surrounds the conductive structure within the conductive via portion 112 (i.e., the conductive via(s) 112a) that surrounded by the etch stop layer 114. In some embodiments, the thickness of the metal-ion-containing dielectric layer 116 is greater than the thickness of the etch stop layer 114. In some embodiments, a top surface of the metal-ion-containing dielectric layer 116 is coplanar to a top surface of the conductive via portion 112. In some embodiments, the combined thickness (e.g., in a range from about 500 Å to about 800 Å) of the etch stop layer 114 and the metal-ion-containing dielectric layer 116 over the etch stop layer 114 is substantially identical to the thickness of the conductive via portion 112. In other words, one or more of the conductive vias (e.g., the conductive via(s) 112a within a single conductive via portion 112) in the metallization structure 102 is laterally surrounded by the stack of the etch stop layer 114 and the metal-ion-containing dielectric layer 116.

In some embodiments, the metal-ion-containing dielectric layer 116 includes an ultra-low-k material. In some embodiments, a dielectric constant of the material in the metal-ion-containing dielectric layer 116 is substantially less than about 2.0, 1.8, or 1.5. In some embodiments, the material of the metal-ion-containing dielectric layer 116 includes metal organic framework (MOF) material. MOF material is a type of highly crystalline organic/inorganic composite complex, which is a class of porous polymers consisting of metal clusters (also known as Secondary Building Units-SBUs) coordinated to organic ligands to form one-, two- or three-dimensional structures. Currently, MOF material can be synthesized by room temperature synthesis, conventional electric heating, microwave heating, electrochemistry, mechanochemistry, and ultrasonic methods.

In some embodiments, the MOF material in the metal-ion-containing dielectric layer 116 is composed of metal ions, organic linkers and guest molecules. In some embodiments, the metal ions in the MOF material can include the ions of zinc (Zn), cobalt (Co), copper (Cu), manganese (Mn), lead (Pb), nickel (Ni), iron (Fe), strontium (Sr), ruthenium (Ru), aluminum (Al), magnesium (Mg), titanium (Ti), zirconium (Zr), or combinations thereof. In some embodiments, the organic linkers in the MOF material can include the chemical functional groups of alcohols, amines, carboxylic acids, amides, pyridines, imidazoles, and combinations thereof. In some embodiments, the guest molecules in the MOF material can include small molecules such CH₃CN, CH₃COOH, 1,4-dioxane, dibenzo-p-dioxin, or perylene.

In some examples, under the aspect of the class of MOF material in the metal-ion-containing dielectric layer 116, the MOF material can include fluorinated MOF (FMOF), isoreticular MOF (IRMOF), or zeolitic imidazolate frameworks (ZIF). Under these classes, in some embodiments, the MOF material in the metal-ion-containing dielectric layer 116 can include FMOF-1, FMOF-3, FN-PCP-1, IRMOF-10, IRMOF-3, ZIF-3, ZIF-SOD-Im, ZIF-2, ZIF-8, or ZIF-71. In some embodiments, the MOF material in the metal-ion-containing dielectric layer 116 can include MIL-53, which was firstly synthesized by the Materials Institute Lavoisier (MIL). In some embodiments, the MOF material in the metal-ion-containing dielectric layer 116 can include a Cu-based MOF such as HKUST-1 or called Cu₃(BTC)₂ MOF, wherein BTC can be recited as 1,3,5-benzene tricarboxylate. In some embodiments, the MOF material in the metal-ion-containing dielectric layer 116 can include a Zn-HKUST-1 or called Zn₃(BCT)₂ MOF.

The metal-ion-containing dielectric layer 116 is substantially one of the layers within the metallization structure. In terms of structural stability and low dielectric constant, the ordered porous structure of the MOF material in the metal-ion-containing dielectric layer 116 enables moderate mechanical properties (e.g., Young's modulus and hardness) at an ultra-low dielectric constant that is no greater than about 2.0, 1.8, or 1.5. The ultra-low dielectric constant can be achieved through the tuning of the selection of metal ions, organic linkers, and guest molecules within the examples disclosed above.

Furthermore, since the metal-ion-containing dielectric layer 116 may cover the metal layers and/or the MEOL structure and FEOL structures below the metallization structure 102. In some embodiments, the hermetic feature of the metal-ion-containing dielectric layer 116 may be enhanced to by using hermetic-oriented MOF material in the metal-ion-containing dielectric layer 116. For instance, in some embodiments, the organic linker in the MOF material can include hydrophobic groups such as long carbon chains (e.g., an alkyl chain), or to use fluorine (F) to substitute aromatic rings, or to add trifluoromethyl (CF3) groups to aromatic rings to increase the hydrophobicity of MOF materials effectively. For example, the MOF materials may include a perfluoroaromatic compound, where fluorine atoms have replaced most or all of the hydrogen atoms in the aromatic rings, or a trifluorotoluene, where one hydrogen atom of the methyl group in a toluene molecule is replaced by a trifluoromethyl group.

In other examples, the MOF material in the metal-ion-containing dielectric layer 116 can contain chemical structures such as decyl group (C10); 3,5-bis(trifluoromethyl)-1,2,4-triazole; 4,4′-(Hexafluoroisopropylidene)diphthalic anhydride; 1,4-bis(tetrazol-5-yl)tetrafluorobenzene; or the like. By increasing the hydrophobicity of MOF materials, the metal-ion-containing dielectric layer 116 can also be serve as water barrier to deposit conductive materials (e.g., the metal line of the metal layers) thereon.

Still referring to FIG. 1, in some embodiments, since the conductive via 112a in the metallization structure 102 is laterally surrounded by the stack of the etch stop layer 114 and the metal-ion-containing dielectric layer 116, it can be said that the conductive via 112a substantially penetrates the stack of the metal-ion-containing dielectric layer 116 and the etch stop layer 114. In some comparative embodiments, the dielectric material (e.g., the low-k dielectric materials called ILDs) deposited over the etch stop layer 114 can be a silicon-based low-k material such as SiCOH, SiO₂, FSG, USG, or the like. In the scenario where this silicon-based low-k material is replaced by the metal-ion-containing dielectric layer 116, which has an ultra-low-k value, the RC delay in the metallization structure 102 can be alleviated due to the decreased dielectric constant. Moreover, by using the organic linker in the MOF material properly, the hydrophobicity of the metal-ion-containing dielectric layer 116 can be ensured.

In addition, in a typical BEOL structure, the metallic material in the metal line portion 110 and the conductive via portion 112 is surrounded by low-k ILDs. As illustrated in FIG. 1, in some embodiments, the metallization structure 102 in the semiconductor structure 10 can include a plurality of ILDs, such as the ILD 128a, 128b, 128c, 128d, and 128e in the figure. There could be more ILDs if the metallization structure 102 includes more metal layers. In some embodiments, the material of ILD includes silicon-based low-k materials such as SiCOH, SiO₂, FSG, USG, or the like. The material of ILD is different from the material of the metal-ion-containing dielectric layer 116, not only from the aspect that the material of ILD does not include metal ion, but also from the aspect that the “low-k” feature of ILD is merely having a dielectric constant (e.g., about 3.5) lower than that of SiO₂ (e.g., about 4.5). The value of the dielectric constant of ILD is much higher than the MOF material used in the metal-ion-containing dielectric layer 116. That is, the dielectric constant of the metal-ion-containing dielectric layer 116 is lower than each of the ILDs in the metallization structure 102. Moreover, regarding the mechanical strength, the mechanical properties (e.g., Young's modulus and/or hardness) of the ILD are greater than the mechanical properties of the metal-ion-containing dielectric layer 116.

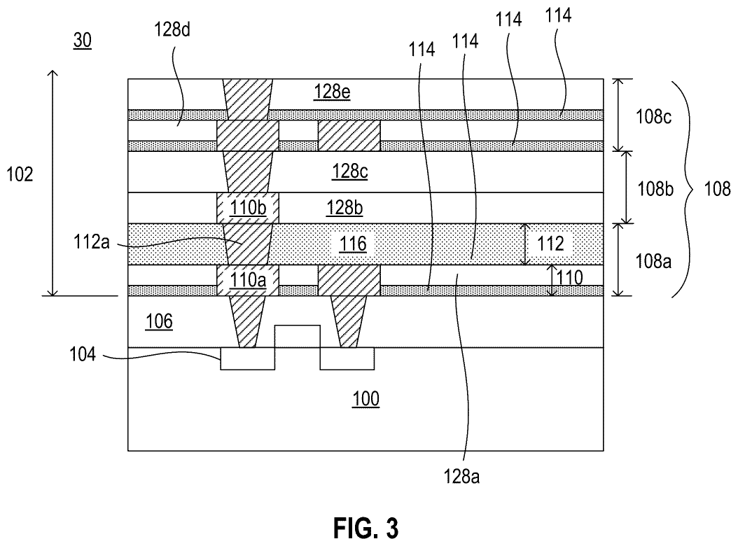

Comparing the embodiments illustrated in FIG. 1 and FIG. 3 (the feature of the embodiment shown in FIG. 3 will be described later), the metallization layer 102 in the semiconductor structure 10 in FIG. 1 includes the etch stop layer 114 under the metal-ion-containing dielectric layer 116. Therefore, the metal-ion-containing dielectric layer 116 formed on it can be free from hydrophobic groups because the hermetic function can be provided by the etch stop layer 114 instead of the metal-ion-containing dielectric layer 116 in this embodiment.

In addition to hydrophobicity, the selection of metal ions, organic linkers, and/or guest molecules in the MOF material may affect the dielectric constant and mechanical properties. Thus, the MOF material not only provides an ultra-low dielectric constant and adequate mechanical strength, but these parameters of the MOF material are also tunable for different types of semiconductor structures or devices.

As illustrated in FIG. 1, in some embodiments, the metal layer 108 containing the metal-ion-containing dielectric layer 116 is substantially sandwiched by two other metal layers 108. In some embodiments, the metal layer 108 in contact with the upper surface of the metal-ion-containing dielectric layer 116 does not include an etch stop layer. The absence of an etch stop layer in the metal layer 108 on the metal-ion-containing dielectric layer 116 is due to the fact that the metal-ion-containing dielectric layer 116 itself can function as an etch stop layer for the metal layer above it during the process of forming the metal line portion 110 of the metal layer 108. Furthermore, the absence of an etch stop layer in the metal layer 108 on the metal-ion-containing dielectric layer 116 can reduce the dielectric constant of materials in the metallization structure 102 (i.e., one of the etch stop layers with a relatively high dielectric constant is not formed), thereby alleviating the RC delay in the metallization structure 102.

In some embodiments, the stack of the metal-ion-containing dielectric layer 116 and the etch stop layer 114 is not formed in the metal line portion 110 of the metal layers 108. This is because the mechanical strength requirements in the metal line portion 110 and the conductive via portion 112 in a single metal layer 108 are different. Typically, the density of conductive vias within the conductive via portion 112 is merely about 1% (i.e., merely about 1% of the total area); meanwhile, the space for forming the metal-ion-containing dielectric layer 116 is relatively wide compared to the situations in the metal line portion 110. Therefore, forming the metal-ion-containing dielectric layer 116 in the conductive via portion 112 of the metal layer 108 can achieve a relatively large reduction in dielectric constant while also ensuring that the overall mechanical strength of the metallization structure 102 is minimally affected by the use of metal-ion-containing dielectric material.

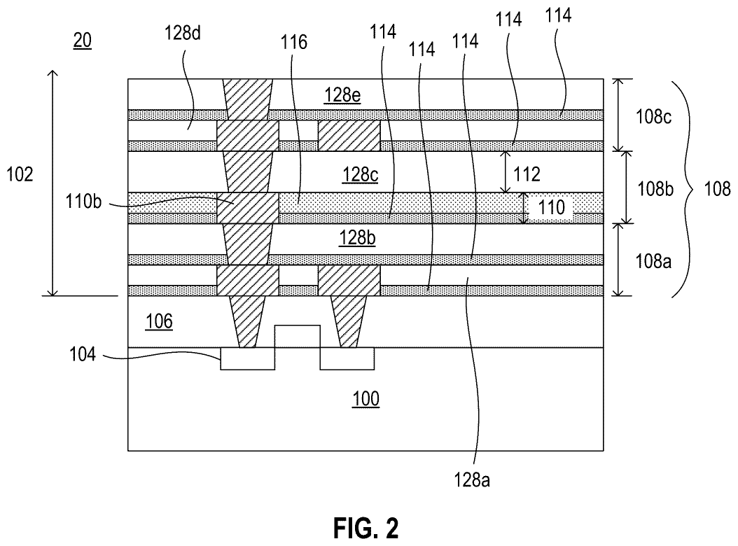

In other embodiments, referring to FIG. 2, for example, the stack of the metal-ion-containing dielectric layer 116 and the etch stop layer 114 can still be formed in the metal line portion 110 of the metal layers 108. This embodiment can be considered in scenarios where the layout design results in a low density of metal lines (e.g., the metal line(s) 110b) within the metal line portion 110, the concern for mechanical strength can be relatively open.

Referring to FIG. 3, in some embodiments, a semiconductor structure 30 includes the substrate 100 and the metallization structure 102 over the substrate 100. In some embodiments, the front-end-of-line (FEOL) structure 104 and/or a middle-end-of-line (MEOL) structure 106 can be formed over the substrate 100 subsequently, prior to the formation of the metallization structure 102.

In the embodiments illustrated in FIG. 3, the metallization structure 102 includes one or more etch stop layers 114 and a metal-ion-containing dielectric layer 116. The conductive via portion 112 of the metal layer 108, which includes the metal-ion-containing dielectric layer 116, does not stack with the etch stop layers 114 in the same metal layer 108. That is, in some embodiments, the metal-ion-containing dielectric layer 116 can be formed directly over the underlying metal layer 108 without forming the etch stop layers 114 in advance.

In some embodiments, the thickness of the metal-ion-containing dielectric layer 116 is substantially identical to the thickness of the conductive via 112a. In some embodiments, the metal-ion-containing dielectric layer 116 is in contact with two metal line portions 110 of two adjacent metal layers 108 (e.g., the metal lines 110a and 110b in the metal layers 108a and 108b) and thus is sandwiched by these metal line portions 110. In some embodiments, not only is a top surface of the metal-ion-containing dielectric layer 116 free from contact with a etch stop layer, but a bottom surface of the metal-ion-containing dielectric layer 116 is free from contact with an etch stop layer.

In some embodiments, a bottom of the conductive via 112a is landing on a top of a metal line in the metal layer 108 under the metal-ion-containing dielectric layer 116 (i.e., the underlying metal layer 108, see the metal line 110a in FIG. 3). In some embodiments, a top critical dimension (TCD) of the metal line in the underlying metal layer 108 is in a range from about 20 nm to about 40 nm. In some embodiments, a bottom critical dimension (BCD) of the conductive via 112a is in a range from about 10 nm to about 20 nm. Because the top critical dimension of the metal line in the underlying metal layer 108 is greater than, or at least no less than the bottom critical dimension of the conductive via 112a, the etching trench for forming the conductive via 112a during the formation of the conductive via 112a can be located directly over the metal line in the underlying metal layer 108 formed in previous operations. Therefore, there is no need to use an etch stop layer in contact with the top surface of the underlying metal layer 108. The absence of an etch stop layer can reduce the dielectric constant of materials in the metallization structure 102, and the RC delay in the metallization structure 102 can be alleviated, as mentioned previously.

In some embodiments, the MOF material in the metal-ion-containing dielectric layer 116 can have different etching selectivity compared to the silicon-based low-k material due to their different elemental compositions. For instance, in a fluorine-based etching operation, the silicon-based low-k material can be etched by the fluorine-based etchant, but not the MOF material. Therefore, in some scenarios, an etch stop layer is not formed because the MOF material in the semiconductor structure can perform the function of an etch stop.

In some embodiments, the semiconductor structure may have more than one metal-ion-containing dielectric layer in the metallization structure, with these metal-ion-containing dielectric layers distributed in different metal layers and laterally surrounding the conductive vias in these metal layers. Since the metal-ion-containing dielectric layer may have an ultra-low dielectric constant, the overall RC delay can be alleviated due to the reduction of the overall dielectric constant in the metallization structure. However, the structural strength of the semiconductor structure should be considered to determine how many metal-ion-containing dielectric layers are going to be formed, which depends on the specifications of each semiconductor structure.

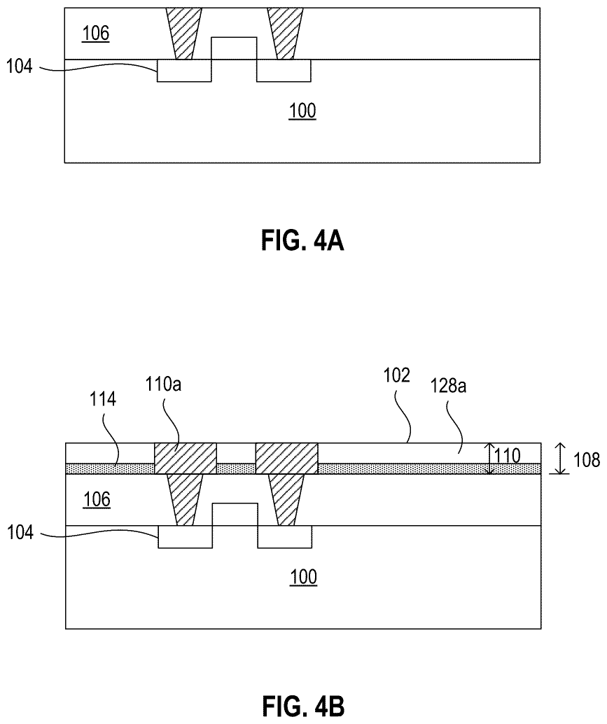

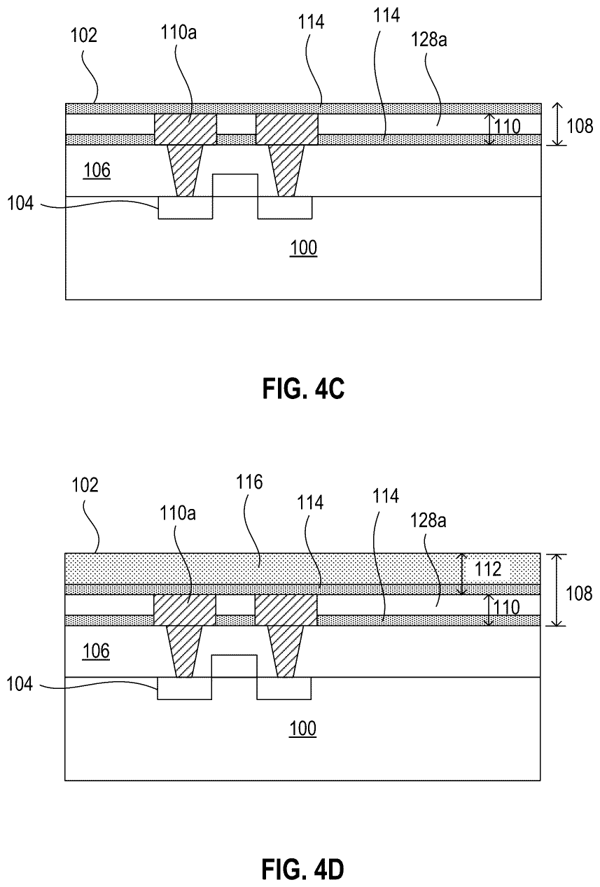

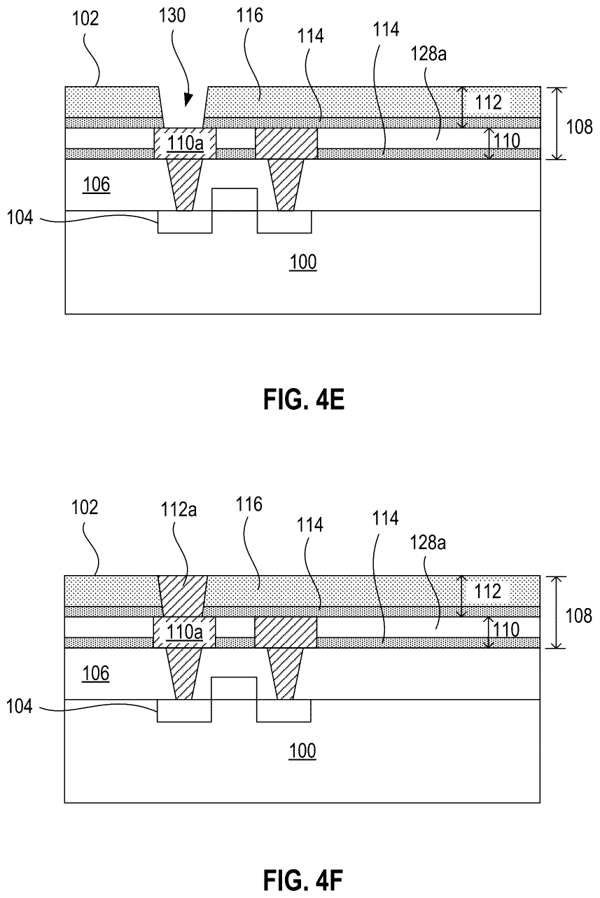

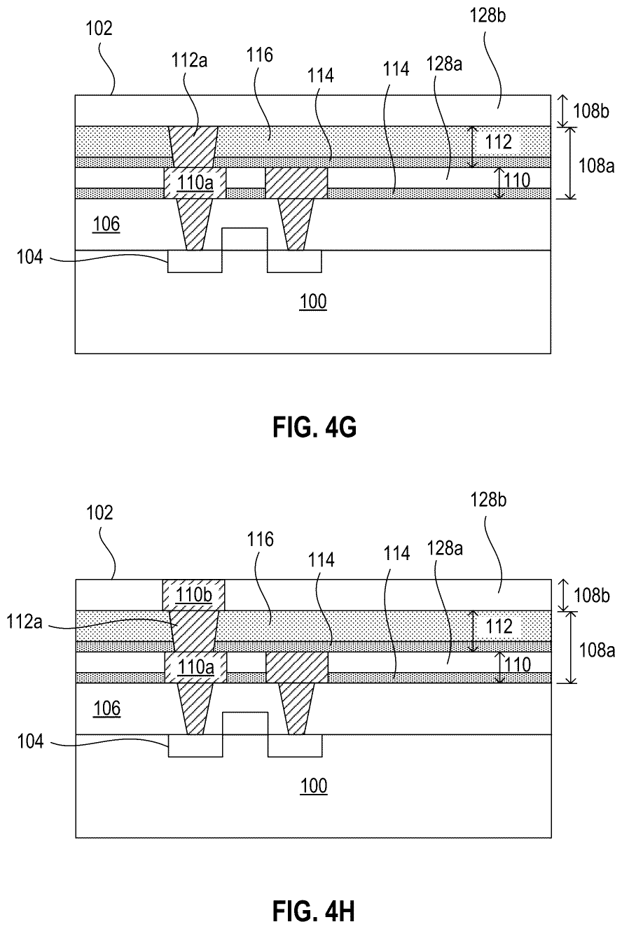

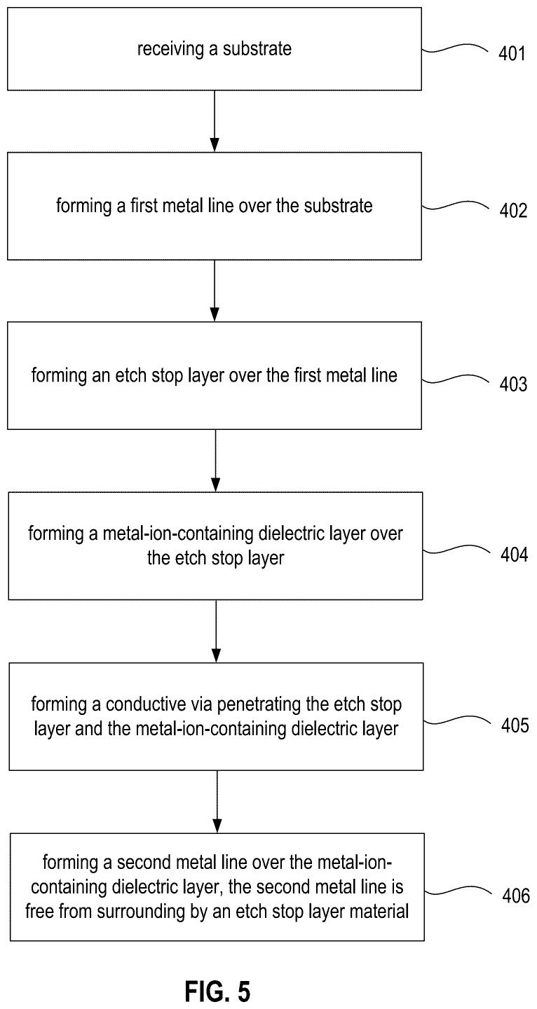

Referring to FIGS. 4A to 4H and FIG. 5, in the method for manufacturing the semiconductor structure in some embodiments of the present disclosure, the operations can include the followings. As illustrated in FIG. 4A and FIG. 5, a substrate 100 can be received (i.e., S401: receiving a substrate). The substrate 100 may have the structures such as the FEOL structure 104 and/or the MEOL structure 106 formed therein/thereon, these structures were previously described in introducing the semiconductor structure in FIG. 1.

Next, in some embodiments, referring to FIG. 4B and FIG. 5, a metallization structure 102 can be formed over the substrate 100. In some embodiment, the metallization structure 102 includes one or more metal layers 108 that having a metal line portion 110. In some embodiments, the metal line portion 110 may include a etch stop layer 114 for forming a first metal line 110a in the metal line portion 110. In the example shown in FIG. 4B, the first metal line 110a can be formed over the substrate 100 (i.e., S402: forming a first metal line over the substrate). In some embodiments, the material of the first metal line 110a can include copper (Cu), cobalt (Co), nickel (Ni), ruthenium (Ru), iridium (Ir), platinum (Pt), rhodium (Rh), iron cobalt (FeCo), iron aluminum (FeAl), or the like. In some embodiments, the first metal line 110a can be formed deposited by the manner of electrochemical plating (ECP), electroless deposition (ELD), or physical vapor deposition (PVD). In some embodiments, the first metal line 110a is laterally surrounded by a dielectric material that typically used in forming an ILD layer 128a (e.g., a silicon-based dielectric material). In some embodiments, the top surface of the first metal line 110a is exposed from the dielectric material for contacting with a conductive via in subsequent operations.

In some embodiments, referring to FIGS. 4C and 4D and FIG. 5, an etch stop layer 114 and a metal-ion-containing dielectric layer 116 can subsequently be formed over the first metal line 110a (i.e., S403: forming an etch stop layer over the first metal line, and S404: forming a metal-ion-containing dielectric layer over the etch stop layer). The etch stop layer 114, in some embodiments, includes materials such as silicon nitride (SiN), silicon carbide (SiC), silicon carbonitride (SiCN), or the like. It can be deposited using methods such as PECVD, PEALD, spin coating, or equivalent techniques.

In some embodiments, the metal-ion-containing dielectric layer 116 consists of a MOF material, which can be applied over the etch stop layer 114 through solvent-based synthesis methods. For instance, metal precursors (providing metal ions) and organic linkers are initially dissolved in solvents like N,N-dimethylformamide (DMF). Subsequently, the solvent mixture containing metal precursors and organic linker is spin-coated onto the etch stop layer 114 to form a film.

The film can then undergo crystallization by heating to a temperature conducive to MOF material crystallization. After crystallization, the film is dried under vacuum or ambient conditions to remove residual solvents, thereby forming the metal-ion-containing dielectric layer 116 over the etch stop layer 114. The composition of metal ions, organic linkers, and guest molecules within the metal-ion-containing dielectric layer 116 is determined by the choice of metal precursors, organic linkers, and solvents during the formation process. Some options of them have been previously described and are omitted here for brevity.

Referring to FIGS. 4E and 4F and FIG. 5, in some embodiments, the stack including the etch stop layer 114 and the metal-ion-containing dielectric layer 116 can be patterned to create a trench 130 for forming a conductive via. The patterning of the etch stop layer 114 and the metal-ion-containing dielectric layer 116 may involve a single etching operation in some embodiments. Alternatively, in other embodiments, the patterning process may have two separate etching operations, depending on the materials used for the etch stop layer 114 and the metal-ion-containing dielectric layer 116, as well as the chosen etchant.

Following the patterning process, the trench 130 can be filled with conductive materials for forming a conductive via 112a, and a subsequent chemical mechanical polishing (CMP) process may be performed (i.e., S405: forming a conductive via penetrating the etch stop layer and the metal-ion-containing dielectric layer). The planarization operation though the CMP process may ensure that the combined thickness of the etch stop layer 114 and the metal-ion-containing dielectric layer 116 is substantially identical to the height of the formed conductive via 112a.

Referring to FIG. 4G, in some embodiments, another ILD layer 128b (e.g., a silicon-based dielectric material) can be formed over the metal-ion-containing dielectric layer 116. In some embodiments, the material of the ILD layer 128b is identical to the material of the ILD layer 128a. In some embodiments, the ILD layer 128b is directly formed on the metal-ion-containing dielectric layer 116 and there is no etching stop layer formed prior to the deposition of the ILD layer 128b.

Referring to FIG. 4H and FIG. 5, in some embodiments, the second metal line 110b is formed within the ILD layer 128b through a process involving the patterning of the ILD layer 128b to create at least one trench, filling the trench with conductive material in the ILD layer 128b, and performing a CMP process to planarize the top surfaces of both the second metal line 110b and the ILD layer 128b. In these embodiments, the second metal line 110b, which is in contact with the conductive via 112a, does not be laterally surrounded by an etch stop layer (i.e., S406: forming a second metal line over the metal-ion-containing dielectric layer, the second metal line is free from surrounding by an etch stop layer material).

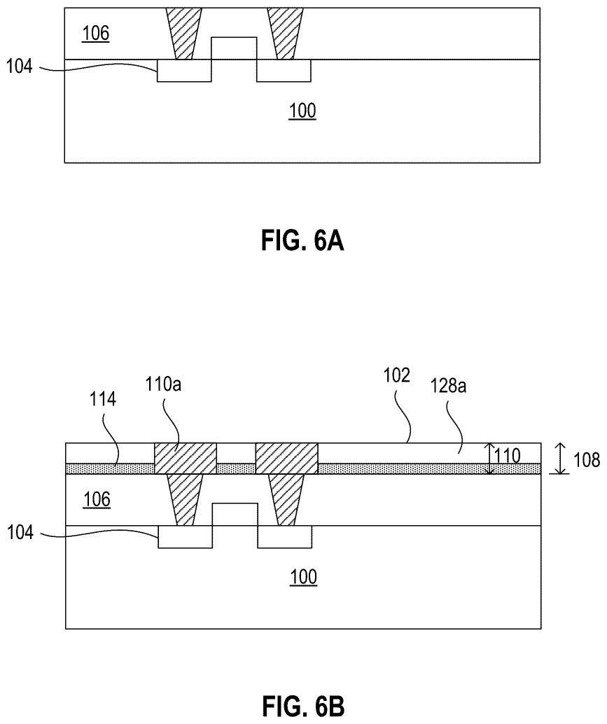

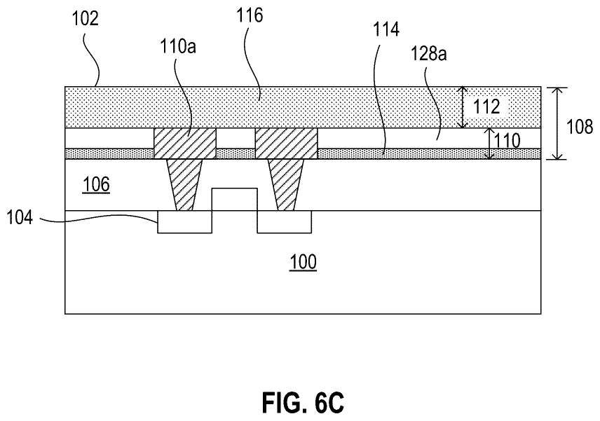

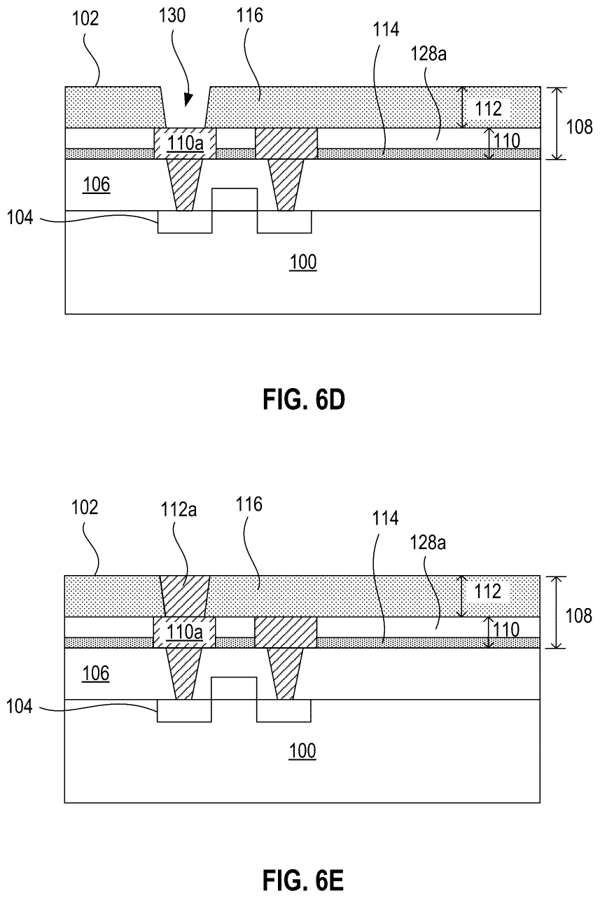

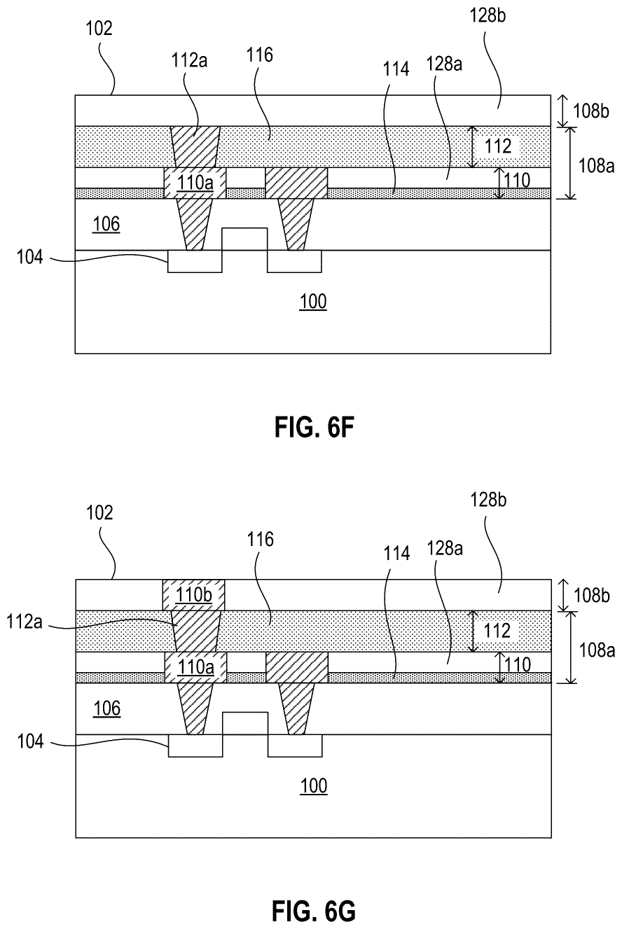

FIGS. 6A to 6G illustrate another embodiment of the present disclosure where no etch stop layer is in contact with the metal-ion-containing dielectric layer 116, such as the embodiment shown in FIG. 3. In this embodiment, the metal-ion-containing dielectric layer 116 can be formed after the formation of the first metal line 110a, without the etch stop layer 114 as shown in FIG. 4C. Since the formation of other operations, corresponding components, and their properties are substantially identical to those disclosed in the embodiment shown FIGS. 4A to 4H and described above, details are omitted here for brevity.

The embodiments illustrated in the present disclosure include one metal-ion-containing dielectric layer 116 formed in the metallization structure 102. However, the present disclosure is not limited to applying only one metal-ion-containing dielectric layer 116 in a semiconductor structure. Each of the metal layers in the metallization structure 102 may be integrated with a metal-ion-containing dielectric layer 116 by replacing ordinary dielectric materials that have a dielectric constant not at an ultra-low level, such as greater than about 2.0. However, as previously mentioned, the mechanical strength of the semiconductor structure should be considered when determining the number of metal-ion-containing dielectric layers in the semiconductor structure.

In one exemplary aspect, a semiconductor structure is provided. The semiconductor structure includes a substrate and a metallization structure over the substrate. The metallization structure includes a plurality of metal layers; an etch stop layer over at least one of the metal layers; a dielectric layer over the etch stop layer, and a conductive via penetrating the etch stop layer and the dielectric layer. The dielectric layer includes a metal-organic framework (MOF) material.

In another exemplary aspect, a semiconductor structure is provided. The semiconductor structure includes a substrate and a metallization structure over the substrate. The metallization structure includes a plurality of metal layers, a metal-ion-containing dielectric layer over at least one of the metal layers, and a conductive via laterally surrounded by the metal-ion-containing dielectric layer.

In yet another exemplary aspect, a method of forming a semiconductor structure is provided. The method includes the operations as follows. A substrate is received. A first metal line is formed over the substrate. A metal-ion-containing dielectric layer is formed over the first metal line. A conductive via is formed and penetrates the metal-ion-containing dielectric layer. A second metal line is formed over the metal-ion-containing dielectric layer. The second metal line is free from surrounding by an etch stop layer material.

The foregoing outlines structures of several embodiments so that those skilled in the art may better understand the aspects of the present disclosure. Those skilled in the art should appreciate that they may readily use the present disclosure as a basis for designing or modifying other operations and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate; and
a metallization structure over the substrate, the metallization structure comprising:
a plurality of metal layers;
an etch stop layer over at least one of the metal layers;
a dielectric layer over the etch stop layer, wherein the dielectric layer comprises a metal-organic framework (MOF) material; and
a conductive via penetrating the etch stop layer and the dielectric layer.

2. The semiconductor structure of claim 1, wherein each of the plurality of metal layers is free from leveling to the dielectric layer comprising the MOF material.

3. The semiconductor structure of claim 1, wherein a thickness of the dielectric layer is greater than a thickness of the etch stop layer.

4. The semiconductor structure of claim 1, wherein a combined thickness of the etch stop layer and the dielectric layer over the etch stop layer is substantially identical to a thickness of the conductive via.

5. The semiconductor structure of claim 1, wherein a top surface of the dielectric layer is coplanar to a top surface of the conductive via.

6. The semiconductor structure of claim 1, wherein a dielectric constant of the dielectric layer is less than about 2.0.

7. The semiconductor structure of claim 1, wherein the MOF material comprises FMOF, IRMOF, or ZIF.

8. The semiconductor structure of claim 1, wherein the MOF material comprises FMOF-1, FMOF-3, FN-PCP-1, IRMOF-10, IRMOF-3, ZIF-3, ZIF-SOD-Im, ZIF-2, ZIF-8, ZIF-71, MIL-53, Cu₃(BTC)₂ MOF, or Zn₃(BTC)₂ MOF.

9. The semiconductor structure of claim 1, wherein an organic linker of the MOF material comprises alcohols, amines, carboxylic acids, amides, pyridines, imidazoles, or combinations thereof.

10. A semiconductor structure, comprising:
a substrate; and
a metallization structure over the substrate, the metallization structure comprising:
a plurality of metal layers;
a metal-ion-containing dielectric layer over at least one of the metal layers; and
a conductive via laterally surrounded by the metal-ion-containing dielectric layer.

11. The semiconductor structure of claim 10, wherein the metal-ion-containing dielectric layer comprises a metal-organic framework (MOF) material having a hydrophobic group.

12. The semiconductor structure of claim 11, wherein the MOF material comprises a decyl group (C10), a 3,5-bis(trifluoromethyl)-1,2,4-triazole, a 4,4′-(Hexafluoroisopropylidene)diphthalic anhydride, or a 1,4-bis(tetrazol-5-yl)tetrafluorobenzene.

13. The semiconductor structure of claim 10, wherein a thickness of the metal-ion-containing dielectric layer is identical to a height of the conductive via.

14. The semiconductor structure of claim 10, wherein a top surface of the metal-ion-containing dielectric layer and a bottom surface of the metal-ion-containing dielectric layer are both free from contact with an etch stop layer material.

15. The semiconductor structure of claim 10, wherein the plurality of metal layers comprises:
a first metal line in contact with a bottom surface of the metal-ion-containing dielectric layer; and
a second metal line in contact with a top surface of the metal-ion-containing dielectric layer.

16. The semiconductor structure of claim 15, wherein the second metal line is free from laterally surrounded by an etch stop layer material.

17. A method of manufacturing a semiconductor structure, the method comprising:
receiving a substrate;
forming a first metal line over the substrate;
forming a metal-ion-containing dielectric layer over the first metal line;
forming a conductive via penetrating the metal-ion-containing dielectric layer; and
forming a second metal line over the metal-ion-containing dielectric layer,
wherein the second metal line is free from surrounding by an etch stop layer material.

18. The method of claim 17, wherein the metal-ion-containing dielectric layer comprises a metal-organic framework (MOF) material having a hydrophobic group.

19. The method of claim 18, wherein the MOF material comprises perfluoroaromatic compound or trifluorotoluene.

20. The method of claim 17, further comprising:
forming an etch stop layer over the first metal line prior to forming the metal-ion-containing dielectric layer.
